(19) United States
(12) Patent Application Publication
(10) Pub. No.: US 2008/0012085 A1
(43) Pub. Date: Jan. 17, 2008

(54) PACKAGING STRUCTURE OF AN OPTICAL MOTION SENSOR

(75) Inventors: Chia-Chu Cheng, Hsin-Tien City (TW); Po-Cheng Chang, Hsin-Tien City (TW); Kuo-Hsien Huang, Hsin-Tien City (TW)

Correspondence Address: ROSENBERG, KLEIN & LEE, 3458 ELLICOTT CENTER DRIVE-SUITE 101, ELLICOTT CITY, MD, 21043, US

(73) Assignee: LITE-ON SEMICONDUCTOR CORP., TAIPEI HSIEN (TW)

(21) Appl. No.: 11/734,960

(22) Filed: Apr. 13, 2007

(30) Foreign Application Priority Data
Apr. 14, 2006 (TW) 95206397

(51) Int. Cl. H01L 31/0203

(52) U.S. Cl. 257/433; 257/E31.117

(57) ABSTRACT

A packaging structure of an optical motion sensor includes a packaging substrate, an optical detection module, and a packaging mask. The optical detection module is provided on the packaging substrate and is electrically connected with the packaging substrate. The packaging mask is disposed on the packaging substrate to package the optical detection module. Further, the packaging mask is provided therein with a transparent body and a hole formed on the packaging mask. Via the above structure, light, passes through the transparent body inside the hole, and thus shines the optical detection module. In this way, the optical detection module is isolated from dirt in the air, thereby reducing possible damage or interference and reducing the volume of the packaging structure.

### BACKGROUND OF THE INVENTION

1. Field of the Invention

The present invention relates to a packaging structure of an optical motion sensor, and in particular to a packaging structure of an optical motion sensor that is composed of complementary metal-oxide-semiconductor (CMOS) sensing chips, disposed on a packaging substrate and covered by a packaging mask.

2. Description of Prior Art

In general, a packaging structure for optical sensing is produced according to the following steps. Firstly, a sensing chip is electrically connected on a dual in-line ingot. Then, via dual in-line packaging (DIP) technology, the dual in-line ingot is electrically connected to a substrate. Finally, a cover is used to finish the packaging process. However, a dual in-line package (DIP) ingot is large in volume and expensive. Further, the manufacturing process is so complex that the resulting structure and the assembly thereof are complicated accordingly, causing a lot of inconvenience.

Please refer to FIG. 1, in which a cross-sectional view of a conventional packaging structure for optical sensing is shown. As shown in this figure, the conventional packaging structure for optical sensing includes a substrate 1a, a dual in-line ingot 2a, a sensing chip 3a, and a cover 4a. The dual in-line ingot 2a has a plurality of pins 20a on both sides and a notch 21a. The sensing chip 3a is electrically connected into the notch 21a. Then, via the action of the pins 20a, the dual in-line ingot 2a is electrically connected to the substrate 1a. Finally, the cover 4a is disposed on the dual in-line ingot 2a so as to package the sensing chip 3a. Furthermore, the substrate 1a has an opening 10a, and the cover 4a has a hole 40a. The hole 40a is provided to correspond to the sensing chip 3a, and the dual in-line ingot 2a is provided to correspond to the opening 10a. In this way, light can illuminate the sensing chip 3a via the hole 40a.

However, the conventional packaging structure for optical sensing still has some drawbacks.
1. Since the packaging structure is produced by means of DIP package technology, the thus-formed packaging structure is large due to its large volume of the dual in-line ingot used by DIP technology.

2. When the sensing chip 3a receives light, it also contacts the dirt in the air. As a result, the increase in contacting dirt causes the sensing chip 3a to be easily damaged and interfered with.

According to the above, the conventional packaging structure for optical sensing still has some inconveniences and drawbacks in practice, and thus needs to be improved.

### SUMMARY OF THE INVENTION

The primary object of the present invention is to provide a packaging structure of an optical motion sensor, in which an optical detection module is disposed on a packaging substrate. Then, a packaging mask having a hole is disposed on the packaging substrate to package the optical detection module when the hole is arranged to correspond to the optical detection module. In addition, the packaging mask is provided therein with a transparent body, so that the optical detection module can be isolated from the dirt in the air, thus reducing the possibility of damage. Therefore, compared with the conventional packaging structure for optical sensing, the present invention is small in volume, simple in structure, and easy to assemble. Further, it is not easily interfered with or damaged.

In order to achieve the above object, the present invention provides a packaging structure of an optical motion sensor, which includes a packaging substrate, an optical detection module, and a packaging mask. The packaging substrate can be a printed circuit board. The packaging mask is made of an opaque material. The optical detection module is provided on the packaging substrate, and is electrically connected with the packaging substrate via a wiring process. The packaging mask is disposed on the packaging substrate to package the optical detection module. The packaging mask has a transparent body made of a glass material, and a hole formed in the packaging mask to correspond to the optical detection module. Via the above structure, a light beam shines into the hole, passes through the transparent body, and shines on the optical detection module.

A main board base is provided on the packaging substrate by means of Surface Mount Technology (SMT). The packaging substrate has at least one through hole. The optical detection module is electrically connected with the main board base directly by means of the wiring process and passing through the at least one through hole.

The optical detection module has at least one transverse line and at least one longitudinal line of complementary metal-oxide-semiconductor (CMOS) linear scanning modules, thereby enhancing the data transmitting speed to replace the traditional planar scanning module.

In order to better understand the technique, measure and effect of the present invention that are adopted to achieve the intended objects, a detailed description thereof will be made with reference to the accompanying drawings. It is apparent that the objects, characteristics and features of the present invention will be further understood in reviewing the following description. However, it should be understood that the drawings and the description are illustrative but not used to limit the scope of the present invention.

### BRIEF DESCRIPTION OF THE DRAWINGS

FIG. 1 is a cross-sectional view showing the conventional packaging structure for optical sensing;

FIG. 2 is a front cross-sectional view showing the packaging structure of an optical sensing module in accordance with the first embodiment of the present invention;

FIG. 3 is an exploded perspective view showing the packaging structure of an optical sensing module in accordance with the first embodiment of the present invention;

FIG. 4 is a front cross-sectional view showing the packaging structure of an optical sensing module in accordance with the second embodiment of the present invention;

FIG. 5 is an exploded perspective view showing the packaging structure of an optical sensing module in accordance with the second embodiment of the present invention;

FIG. 6 is a top view showing the optical detection module of the packaging structure of an optical sensing module in accordance with the present invention.

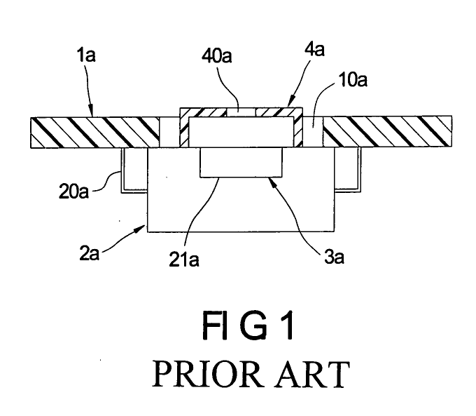

### DETAILED DESCRIPTION OF THE INVENTION

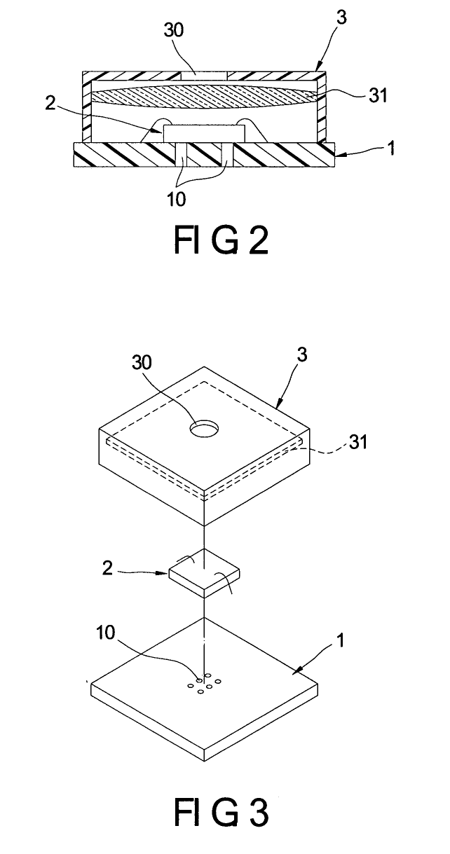

Please refer to FIGS. 2 and 3, in which a front cross-sectional view and an exploded perspective view of the packaging structure of an optical motion sensor in accordance with the first embodiment of the present invention are shown. As shown in these figures, the packaging structure of an optical motion sensor in accordance with the present invention includes a packaging substrate 1, an optical detection module 2, and a packaging mask 3. The packaging mask 3 has a hole 30. The optical detection module 2 is provided on the packaging substrate 1, and is electrically connected with the packaging substrate 1 via a wiring process. The packaging mask 3 is disposed on the packaging substrate 1 to package the optical detection module 2 while the hole 2 is arranged to correspond to the optical detection module 2. Further, the packaging mask 3 is provided therein with a transparent body 31 made of a glass material. Via this arrangement, a light beam shines the optical detection module 2 through the transparent body 31 in the hole 30. The packaging substrate 1 is a printed circuit board (PCB), an aluminum substrate or a flexible printed circuit.

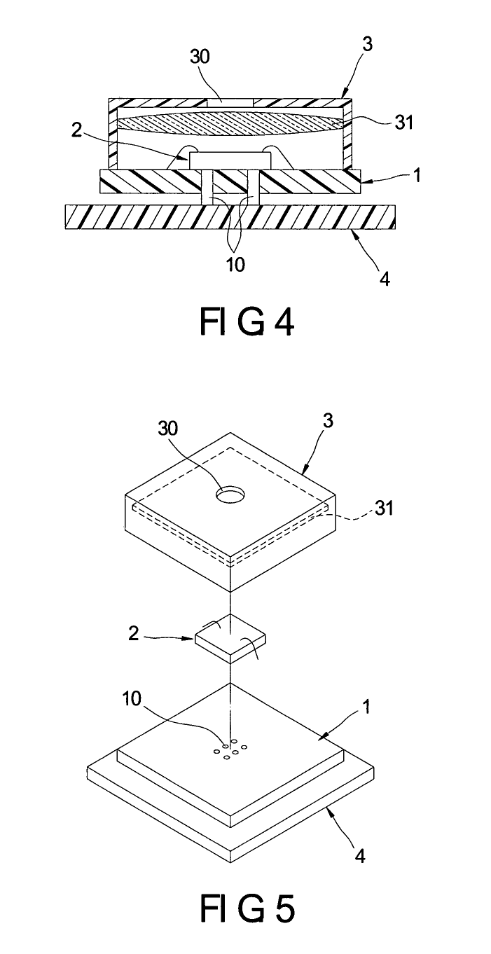

Please refer to FIGS. 4 and 5, in which a front cross-sectional view and an exploded perspective view of the packaging structure of an optical motion sensor in accordance with the second embodiment of the present invention are shown. As shown in these figures, the packaging structure of an optical motion sensor in accordance with the present invention further includes a main board base 4 that is connected to the packaging substrate 1 by means of Surface Mount Technology (SMT). The packaging substrate 1 has at least one through hole 10. The optical detection module 2 is electrically connected with the main board base 4 directly by means of a wiring process and passing through the at least one through hole 10.

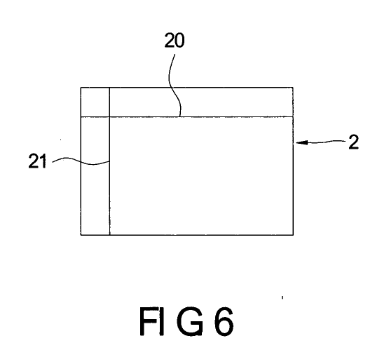

Please refer to FIG. 6, in which a top view of the optical detection module of the packaging structure of an optical motion sensor in accordance with the present invention is shown. As shown in these figures, the optical detection module 2 is comprised of at least one transverse line 20 and at least one longitudinal line 21 of complementary metal-oxide-semiconductor (CMOS) linear scanning modules.

According to the above, the packaging structure of an optical motion sensor in accordance with the present invention has the following advantages:
1. Reducing the manufacturing time and the related costs.
2. Reducing the volume of the packaging structure.
3. The structure is simple and easy to assemble.
4. The optical detection module is isolated from dirt in the air, thereby reducing possible damage and interference.
5. The use of the complementary metal-oxide-semiconductor (CMOS) linear scanning modules enhances the data transmitting speed of the optical detection module.

Although the present invention has been described with reference to the foregoing preferred embodiments, it will be understood that the invention is not limited to the details thereof. Various equivalent variations and modifications may occur to those skilled in this art in view of the teachings of the present invention. Thus, all such variations and equivalent modifications are also embraced within the scope of the invention as defined in the appended claims.

What is claimed is:

1. A packaging structure of an optical motion sensor, comprising:
a packaging substrate;
an optical detection module provided on the packaging substrate and electrically connected with the packaging substrate, the optical detection module including at least one transverse line and at least one longitudinal line of complementary metal-oxide-semiconductor (CMOS) linear scanning modules; and
a packaging mask provided on the packaging substrate to package the optical detection module, the packaging mask being provided therein with a transparent body and a hole formed on the packaging mask.

2. The packaging structure of an optical motion sensor according to claim 1, further comprising a main board base that is provided on the packaging substrate by means of Surface Mount Technology (SMT).

3. The packaging structure of an optical motion sensor according to claim 2, wherein the packaging substrate has at least one through hole, and the optical detection module is electrically connected with the main board base directly by means of a wiring process and passing through the at least one through hole.

4. The packaging structure of an optical motion sensor according to claim 1, wherein the packaging substrate is a printed circuit board (PCB), an aluminum substrate or a flexible printed circuit.

5. The packaging structure of an optical motion sensor according to claim 1, wherein the optical detection module is electrically connected with the packaging substrate by means of a wiring process.

6. The packaging structure of an optical motion sensor according to claim 1, wherein the optical detection module is comprised of complementary metal-oxide-semiconductor (CMOS) sensing chips.

7. The packaging structure of an optical motion sensor according to claim 1, wherein the hole is arranged to correspond to the optical detection module.

8. The packaging structure of an optical motion sensor according to claim 1, wherein the transparent body is a glass body, thereby protecting the optical detection module and isolating the optical detection module from dirt or impurities.

9. The packaging structure of an optical motion sensor according to claim 1, wherein the packaging mask is a packaging mask made of an opaque material.
